(19) United States
(12) Patent Application Publication
(10) Pub. No.: US 2025/0079071 A1
(43) Pub. Date: Mar. 6, 2025

(54) MAGNETIC SHIELDING SYSTEM FOR A DIFFERENTIAL CURRENT TRANSFORMER IN A CIRCUIT BREAKER TO PROVIDE SHIELDING AT MULTIPLE LOCATIONS

(71) Applicant: Siemens Industry, Inc., Alpharetta, GA (US)

(72) Inventors: James Edward Ferree, Lawrenceville, GA (US); Scott Turner, Lilburn, GA (US); Kevin R. Warne, Tucker, GA (US)

(73) Assignee: Siemens Industry, Inc., Alpharetta, GA (US)

(21) Appl. No.: 18/458,299

(22) Filed: Aug. 30, 2023

(51) Int. Cl. H01F 27/28; H01F 38/30

(52) U.S. Cl. CPC H01F 27/2885; H01F 38/30

(57) ABSTRACT

A magnetic shielding system is provided for a Differential Current Transformer to provide shielding at multiple locations for a circuit braker. It comprises an outer shield being cylindrically-shaped and closely fitting and an inner shield being closely fitting over four conductor cables that pass through the Differential Current Transformer. An inside diameter of the inner shield is less than 1.5 times the diameter of the smallest circle that can enclose the four conductor cables that pass through the Differential Current Transformer. In an axial direction, the magnetic shielding system comprises multiple layers of flat, washer-shaped parts in which at least one layer on top and one layer on bottom is of magnetic shielding material. Magnetic shielding is provided at the multiple locations using two or more different classes of materials.

### BACKGROUND

### 1. Field

Aspects of the present invention generally relate to a magnetic shielding system for a Differential Current Transformer in a circuit breaker to provide shielding at multiple locations.

### 2. Description of the Related Art

Ground fault circuit interrupters (GFCIs) in general are designed to trip when there is an imbalance between the currents flowing to the load. Under normal conditions, the load currents are balanced. In a single-phase GFCI, the current flowing to the load is normally equal and opposite to the current in the return wire. In other words, the sum of the currents flowing in the 2 wires sums to zero under normal conditions. In a 3-phase GFCI, the sum of all 3 phases, and neutral wire if present, will sum to zero under normal conditions. On the other hand, if there is a failure of insulation in the load circuit or direct contact with live parts, some of the current may flow to ground instead of returning through the wires. This results in an imbalance of current in the wires, which can be detected by the current transformer of a GFCI and can be used as a criterion for tripping the breaker. Ground fault currents are undesirable because they may cause dangerous and potentially fatal electric shocks to humans or damage to equipment. GFCIs are useful safety devices that protect human lives or prevent damage to equipment. Ideally, a differential current transformer (CT) responds to the sum of the primary currents linked through the opening (the window, or hole) of the ferromagnetic core. Under normal conditions, with no ground fault present, the sum of the primary currents is zero at every moment in time. The problem arises when the behavior of the CT departs from ideal transformer behavior to a degree that exceeds allowable tolerances.

The first and main problem to be solved is flux concentrations in the CT core which cause inaccurate output. The problem arises when attempting to develop a GFCI with high continuous current ratings, such as higher than 60A, when it is also desired that the CT should be small and compact. For example, it may be desired that the CT should be located inside a circuit breaker housing.

Core materials for GFCI differential CTs are typically alloys of nickel, comprising approximately 80% nickel and the balance iron and other elements. These core materials have extremely high relative magnetic permeabilities ranging from 40,000 to 400,000. Because of this, they are extremely sensitive. In the presence of applied magnetic fields, even very weak fields, they strongly amplify the magnetic field. Unfortunately, this not only makes them useful as sensitive current sensors, but also makes them susceptible to both saturation and the influence of external magnetic fields.

The voltage output from the secondary winding of a current transformer is presumably proportional to the primary current, according to the well-known linear behavior of ideal transformers. However, ideal transformer behavior depends on constant magnetic permeability. As an example, let's consider a 1-phase GFCI differential CT with 2 wires. Equal current is flowing in opposite directions in the 2 wires. The flux is higher intensity where the core is closer to a wire. But there are two wires, and the flux flows in opposite directions on opposite sides of the core. If the secondary winding is uniformly wound, and if the permeability of the core constant, then the sum of the voltages induced in each turn of the secondary winding will add up to zero, so that the net voltage on the secondary winding is zero. However, if the permeability of the core is not constant, then any asymmetry of positioning of the two wires in the core may result in a non-zero net voltage, and then the transformer may give non-linear behavior. Likewise, this example can be extended to the case of a 3-phase differential CT. In general, if the flux intensity of the core is acting within a linear range, then the secondary output voltage will be accurate, and zero net primary current results in zero secondary voltage.

CT core materials behave with constant permeability only when the flux intensity is below a threshold value known as the saturation flux intensity Bₛₐₜ. Above Bₛₐₜ, the permeability reduces to a much smaller value. Therefore, a differential CT gives accurate output only when the flux intensity is less than Bₛₐₜ. Therefore, one of the problems to be solved is when the positioning of the primary wires causes a local high flux intensity in the core that exceeds Bₛₐₜ. This will cause a loss of accuracy in the secondary voltage and may result in non-zero secondary voltage even when the sum of the primary currents is zero.

Further intensifying the problem is the need to make a GFCI small and compact. This requires the CT to be as small as possible, so the primary wires are crowded into the core opening and tend to be positioned close to the core. The primary wires may be bent close to the CT, so that the primary wires are close to the top and bottom of the CT. This causes further intensification of the flux.

Magnetic cores of GFCI CTs are usually laminated to reduce eddy currents and in some cases for manufacturing reasons. Some core materials, such as amorphous and nanocrystalline types, are produced as thin ribbons, because they are cooled extremely rapidly from the molten state to develop their magnetic properties.

Laminated cores are constructed in 2 different ways:

Ring laminations are washer-shaped pieces that are stamped from sheet material. They are stacked in the axial direction of the toroid.

Tape-wound cores are produced from a single long ribbon of material that is wound in a spiral.

In addition to flux concentrations originating from the load wires, there may also be magnetic fields from sources external to the GFCI that penetrate the GFCI and influence the differential CT. External sources of fields may include adjacent circuit breakers and wires routed inside the electrical panel near the GFCI. These fields may influence portions of the secondary winding and induce false output.

A further problem is that it is desirable to provide a GFCI circuit breaker with high continuous current ratings, for example greater than 60A, such circuit breaker having not only ground fault protection but also overload and short circuit protection, in a compact size so that the GFCI circuit breaker has the differential CT located inside the breaker housing.

Therefore, improved Ground fault circuit interrupters (GFCIs) are needed with better magnetic shielding.

### SUMMARY

Briefly described, aspects of the present invention relate to a shielding system for a Differential Current Transformer to provide shielding at multiple locations. Differential current transformers (CTs) sense ground fault currents (aka. earth leakage currents) in ground fault circuit interrupters (GFCIs), residual current detectors (RCDs) and residual current circuit breakers (RCCBs). Present invention is not only effective at eliminating flux concentrations in the core, but it is also effective at improving shielding from external magnetic field sources.

Present invention has a magnetic shielding system comprised of multiple parts. Separate parts are provided for shielding at four different locations: radially inside, radially outside, and both sides axially. This allows different materials to be used at each location. The shielding requirements at each of these locations varies. Present shielding system allows materials to be optimized for each location. Shielding parts are optimized by material, thickness and number of layers. The shielding system is customizable, allowing materials to be changed as needed for varying applications.

Further, present shielding system may be optimized according to cost. Special shielding materials such as mumetal are expensive due to the high nickel content and elaborate annealing process. Present shielding system allows that the use of special materials is kept to a minimum, only at specific locations, and lower-cost materials may be used at other locations.

Present shielding system selects from the following four classes of shielding materials. There is a clear tradeoff between permeability on the one hand and cost on the other hand.

TABLE I

| | | | Saturation | |
|---|---|---|---|---|
| | | Max relative | Flux Intensity | |
| | Example | permeability | Bₛₐₜ | |
| Material type | material | μᵣ | [Tesla] | Cost |
| 80% Ni, | mumetal | 300,000 | 0.8 | High |
| balance mostly | | | | |
| Fe | | | | |
| 49% Ni, | AD-MU-48 | 130,000 | 1.5 | High |
| balance mostly | | | | |
| Fe | | | | |
| Silicon | Type M-15 | 8,000 | 2.1 | Low |
| electrical steels | | | | |
| or high-purity | | | | |
| iron | | | | |
| Commercial | Type 1008 | 2,000 | 2.1 | Very low |
| low-carbon | | | | |
| steel | | | | |

In accordance with one illustrative embodiment of the present invention, a magnetic shielding system is provided for a Differential Current Transformer to provide shielding at multiple locations for a circuit braker. It comprises an outer shield being cylindrically-shaped and closely fitting and an inner shield being closely fitting over four conductor cables that pass through the Differential Current Transformer. An inside diameter of the inner shield is less than 1.5 times the diameter of the smallest circle that can enclose the four conductor cables that pass through the Differential Current Transformer. In an axial direction, the magnetic shielding system comprises multiple layers of flat, washer-shaped parts in which at least one layer on top and one layer on bottom is of magnetic shielding material. Magnetic shielding is provided at the multiple locations using two or more different classes of materials.

In accordance with one illustrative embodiment of the present invention, a magnetic shielding system is provided for a Differential Current Transformer to provide shielding at multiple locations for a circuit breaker. The magnetic shielding system comprises a magnetic core that may be either ring laminations or tape-wound, a first layer axial shields (top and bottom made of any magnetic shielding material from 80% Ni class of materials), a first layer radial shields (inner and outer made of any magnetic shielding material from 80% Ni class of materials), a second layer radial inner shield, a second layer radial outer shield, a second layer axial shield bottom and a housing of the Differential Current Transformer, wherein shielding is characterized by a 2-layer shielding system. Both first and second layers of shielding are present at locations: radially inside, radially outside, and axially top and bottom. A material of the second layer of shielding surrounds the first layer of the shielding, and wherein the first layer of shielding is nearest to the core.

The above described features and advantages, as well as others, will become more readily apparent to those of ordinary skill in the art by reference to the following detailed description and accompanying drawings. While it would be desirable to provide one or more of these or other advantageous features, the teachings disclosed herein extend to those embodiments which fall within the scope of the appended claims, regardless of whether they accomplish one or more of the above-mentioned advantages.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects.

FIGS. 1-3 illustrate most critical locations for shielding for a ring lamination core in accordance with an embodiment of the present invention. Three different views are shown of the same set of parts.

FIGS. 4-6 illustrate most critical locations for shielding for a tape wound core in accordance with an embodiment of the present invention. Three different views are shown of the same set of parts.

FIG. 7 illustrates a GFCI circuit breaker with a Differential Current Transformer (CT) having a magnetic shielding of either FIGS. 1-3 or FIGS. 4-6 in accordance with an embodiment of the present invention.

FIG. 8 illustrates the same FIG. 7 but with a cover removed, exposing the Differential Current Transformer (CT) in accordance with an embodiment of the present invention.

FIG. 9 illustrates a CT module of the circuit breaker of FIG. 7 in accordance with an embodiment of the present invention.

FIG. 10 illustrates a top view of the CT module of the circuit breaker of FIG. 7 in accordance with an embodiment of the present invention.

FIG. 11 illustrates a view of a circuit board for the Differential Current Transformer (CT) in accordance with an embodiment of the present invention. A cutting plane A-A is shown for cross-sectional views.

FIG. 12 illustrates a section view of a first embodiment of the present invention (a ring lamination core).

FIG. 13 illustrates an enlarged section view of the first embodiment of the present invention.

FIG. 14 illustrates a section view of a second embodiment of the present invention (a tape wound core).

FIG. 15 illustrates an enlarged section view of the second embodiment of the present invention.

FIG. 16 illustrates an enlarged section view of a third embodiment of the present invention which provides higher magnetic shielding performance than the first and second embodiments.

FIG. 17 shows a magnetic simulation setup.

FIG. 18 shows a worst-case magnetic field intensity on a cross-section of the setup of FIG. 17.

FIG. 19 shows a maximum net flux around the magnetic core for the setup shown in FIG. 17.

### DETAILED DESCRIPTION

Various technologies that pertain to systems and methods that provide a circuit breaker with a Current Transformer (CT) having a magnetic shielding at multiple locations are presented. The drawings discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged apparatus. It is to be understood that functionality that is described as being carried out by certain system elements may be performed by multiple elements. Similarly, for instance, one element may be configured to perform functionality that is described as being carried out by multiple elements. The numerous innovative teachings of the present application will be described with reference to exemplary non-limiting embodiments.

To facilitate an understanding of embodiments, principles, and features of the present invention, they are explained hereinafter with reference to implementation in illustrative embodiments. In particular, they are described in the context of a circuit breaker with a Current Transformer (CT) having a magnetic shielding at multiple locations. Embodiments of the present invention, however, are not limited to use in the described devices or methods.

The components and materials described hereinafter as making up the various embodiments are intended to be illustrative and not restrictive. Many suitable components and materials that would perform the same or a similar function as the materials described herein are intended to be embraced within the scope of embodiments of the present invention.

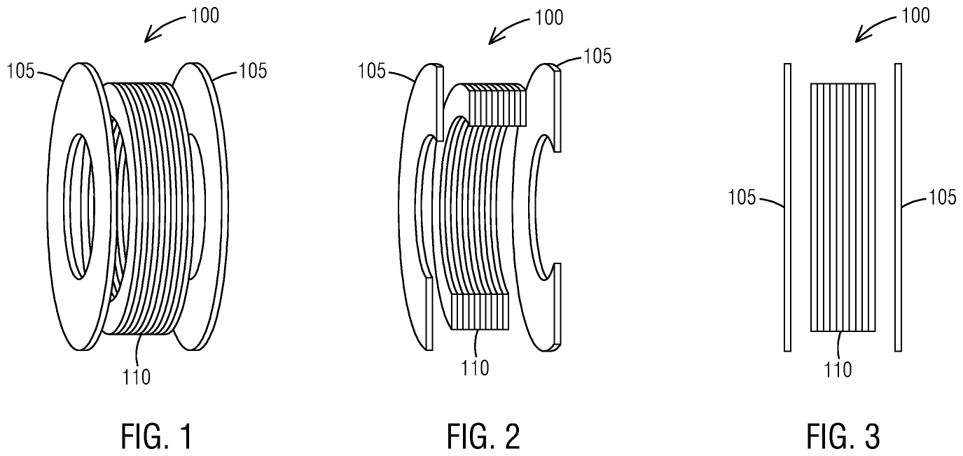

These and other embodiments of the system are provided for providing a circuit breaker with a Current Transformer (CT) having a magnetic shielding at multiple locations according to the present disclosure are described below with reference to FIGS. 1-16 herein. The drawing is not necessarily drawn to scale.

Present shielding system leverages the following design principles:

Weak magnetic fields are best blocked by high permeability materials, such as mumetal. But these materials cannot block strong magnetic fields because of the lower saturation level.

Strong magnetic fields are best blocked by high saturation materials, such as low-carbon steel. But these materials allow weak magnetic fields to pass through.

Increasing thickness of a material improves blocking performance for both strong and weak fields.

The four different locations differ in their application requirements as follows:

### Radial Inside Location

a. Magnetic fields are strongest, due to proximity of primary wires.
b. Space is limited. Steel is insufficient when only 1 layer is available, because too much field will pass through.
c. Cylindrical shape rules out silicon steel which is supplied in flat stock and has poor formability.
d. Mumetal is chosen but must be sufficiently thick to block strong fields.

### Axial Top and Bottom Locations

a. Magnetic fields are strong due to tight bending of wires.
b. Shape requirement is flat, so silicon steel is a good candidate. Flat, washer-shaped parts can be produced at low cost.
c. Silicon steel is chosen because it is much cheaper than nickel-containing materials and has higher permeability than commercial low-carbon steel.
d. Multiple thicknesses can be stacked to block strong fields.

### Radially Outside Location

a. Sources of magnetic fields are relatively far away, so magnetic fields are weak. Sources may be internal conductors of the circuit breaker (further away) or external devices and wiring.
b. A deep-drawn cylindrical cup-shape is a low-cost way to produce a cylindrical shape. The top of the cup-shape is also desirable for mechanically retaining parts of the CT assembly.
c. Material can sometimes be thinner because fields are weaker.
d. Cylindrical shape rules out silicon steel.
e. First choice is low-carbon steel, which is easily deep-drawn.
f. However, a tape-wound core may not be sufficiently protected by low-carbon steel, because its radially outside lamination is extremely susceptible to weak magnetic fields. In this case, a mumetal part may be substituted.

The above reasoning explains the choices in our application. But the relative importance of the deciding factors will vary with other applications and may evolve over time. For example, costs of materials may change. Present invention is not intended to be limited to one selection or combination of materials. Rather, we have provided a flexible system that can be adapted according to different needs.

Instant magnetic shielding system may be customized to achieve the unique and different requirements of ring laminations cores versus tape-wound cores. Prior art has not recognized the different behavior of these two types of cores, nor has attempted to design a shielding system specific to the type of core.

Furthermore, present invention extended the inventive concept to a very high-performance variation. With a modest increase in size, a 2-layer shielding system was achieved that attenuates magnetic fields multiple orders of magnitude more than our 1-layer combinations.

FIGS. 1-3 illustrate most critical locations for shielding for a ring lamination core 100 in accordance with an embodiment of the present invention. Three different views are shown of the same set of parts. Top and bottom shields 105 are offset in an axial direction from the top and bottom ring laminations 110, respectively. The ID and OD edges of the shields extend past the ID and OD edges of the ring laminations of the core, respectively, for a distance of at least 1 thickness of the shield.

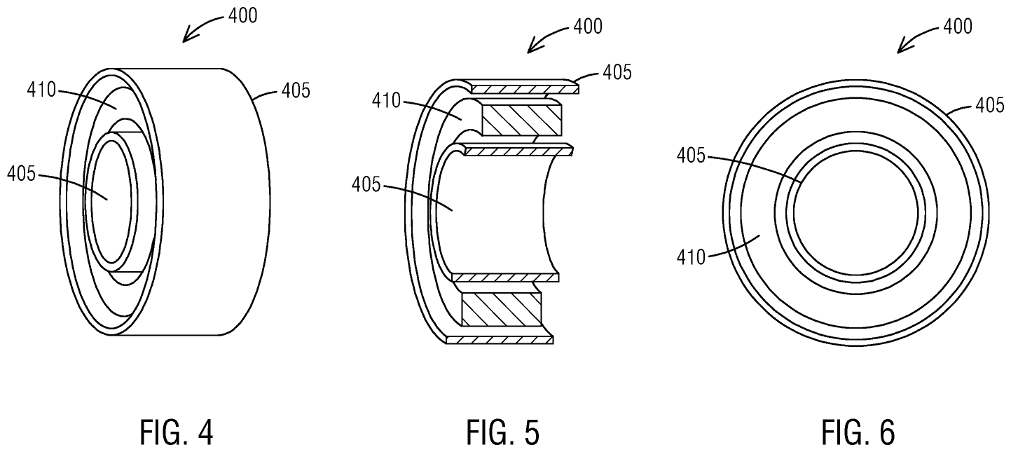

FIGS. 4-6 illustrate most critical locations for shielding for a tape wound core 400 in accordance with an embodiment of the present invention. Three different views are shown of the same set of parts. Inner and outer shields 405 are offset in the radial direction from the inner and outer laminations of the tape wound core 410, respectively. The top and bottom edges of the shields extend past the top and bottom edges of the tape ribbon of the core, respectively, for a distance of at least 1 thickness of the shield.

Via computer simulations it is determined that when CT cores are laminated, there is an additional factor that greatly intensifies the problem. Laminated cores combined with high permeability materials result in high flux concentrations on the two exposed sides of the stack. This is because a stack of laminations has much lower permeability in the stacking direction than within the length and width directions of the laminations. In laminated cores, externally applied magnetic fields do not penetrate to the full depth of the core in the stacking direction. Rather, magnetic fields concentrate in the outside layers of the stack. The reason for reduced permeability in the stacking direction is air gaps between laminations. Laminations are not perfectly flat and may have an oxide layer or insulation coating. As a result, a fraction of the volume, only 80-95% (called the stacking factor) is magnetic material and the rest is non-magnetic volume.

Laminated cores are constructed in 2 different ways, and accordingly the problem of high flux concentrations manifests itself differently, depending on which construction is used. Nevertheless, the result is the same, that is, high flux concentrations increase the likelihood of exceeding Bₛₐₜ.

With ring laminations, flux concentrations tend to occur in the laminations at the top and bottom of the stack.

With tape-wound cores, flux concentrations tend to occur in the inside and outside layers of the spiral.

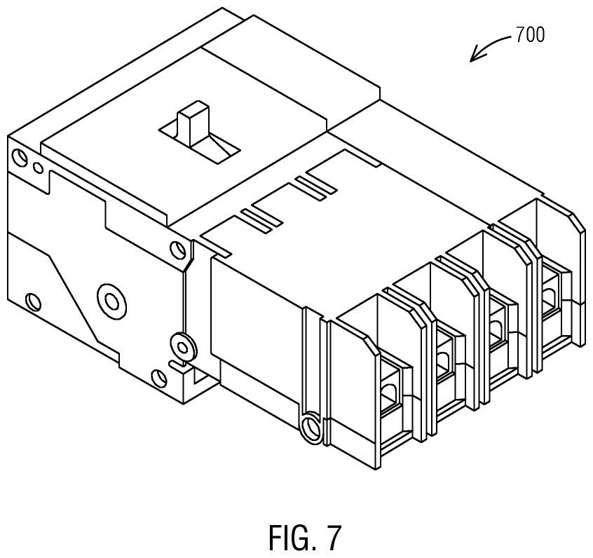

FIGS. 7 through 11 show the context of instant invention, which is a 3-phase GFCI circuit breaker rated 100A continuous current. The breaker conforms to both UL 943 as a GFCI and UL 489 as a circuit breaker.

In FIG. 7, it illustrates a GFCI circuit breaker 700 with a Differential Current Transformer (CT) (not seen) having a magnetic shielding of either FIGS. 1-3 or FIGS. 4-6 in accordance with an embodiment of the present invention. The GFCI circuit breaker 700 incorporates the present invention. It is made possible by the compact size. This is a 100A continuous current 3-phase breaker rated at 240V. It conforms to UL 943 as a GFCI, and it also has overload and short circuit protection conforming to the circuit breaker requirements of UL 489.

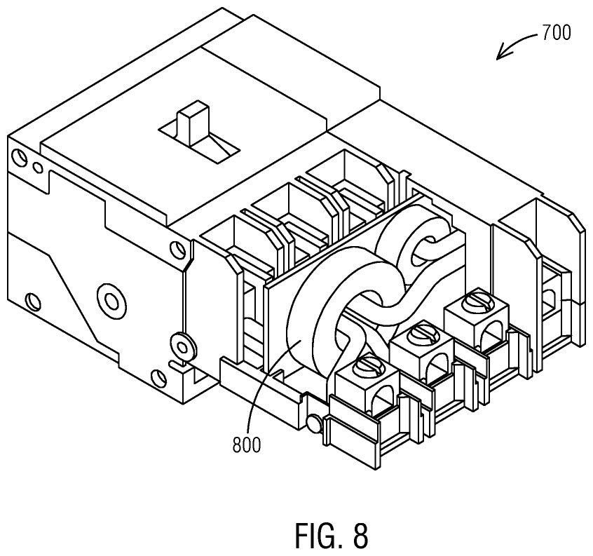

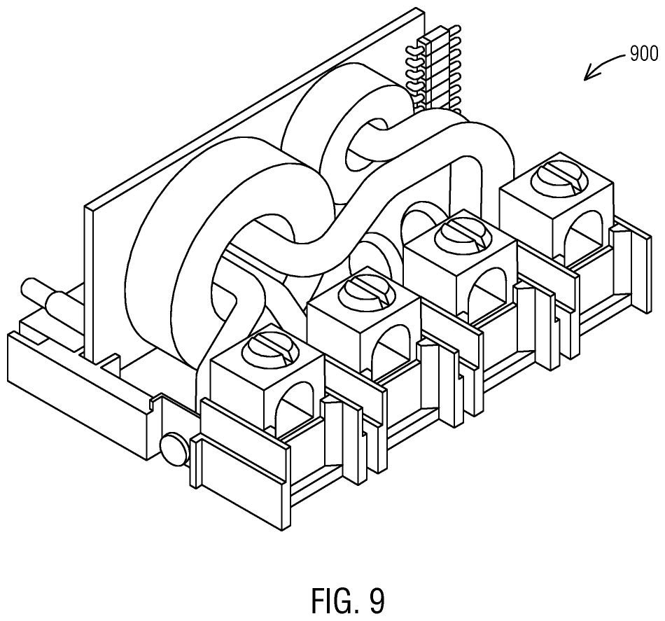

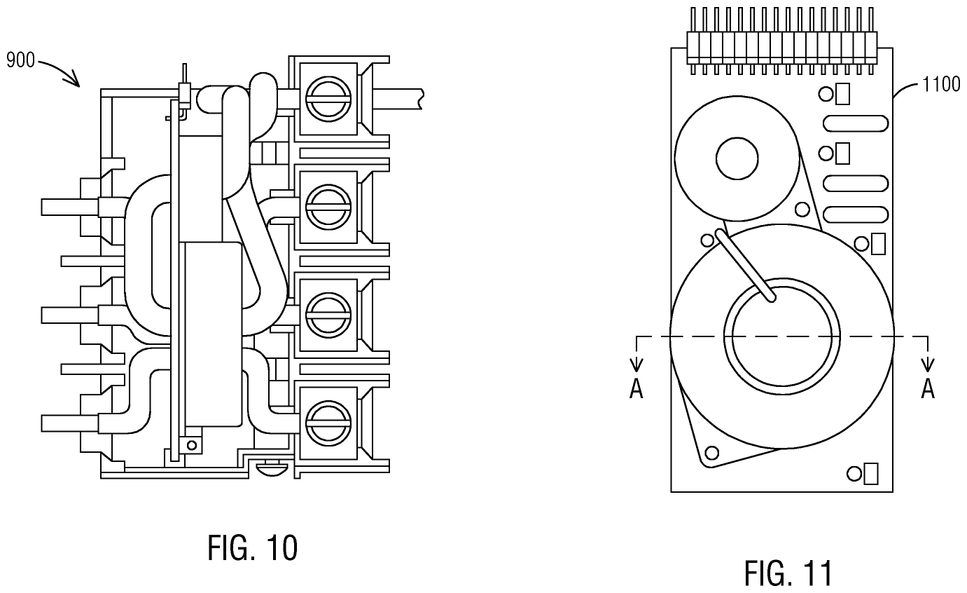

With regard to FIG. 8, it illustrates the same FIG. 7 but with a cover removed, exposing the Differential Current Transformer (CT) 800 in accordance with an embodiment of the present invention. With respect to FIG. 9, it illustrates a CT module 900 of the circuit breaker 700 of FIG. 7 in accordance with an embodiment of the present invention. FIG. 10 illustrates a top view of the CT module 900 of the circuit breaker 700 of FIG. 7 in accordance with an embodiment of the present invention. FIG. 11 illustrates a view of a circuit board 1100 for the Differential Current Transformer (CT) in accordance with an embodiment of the present invention. A cutting plane A-A is shown for cross-sectional views.

The next FIGs. show three embodiments of present invention.

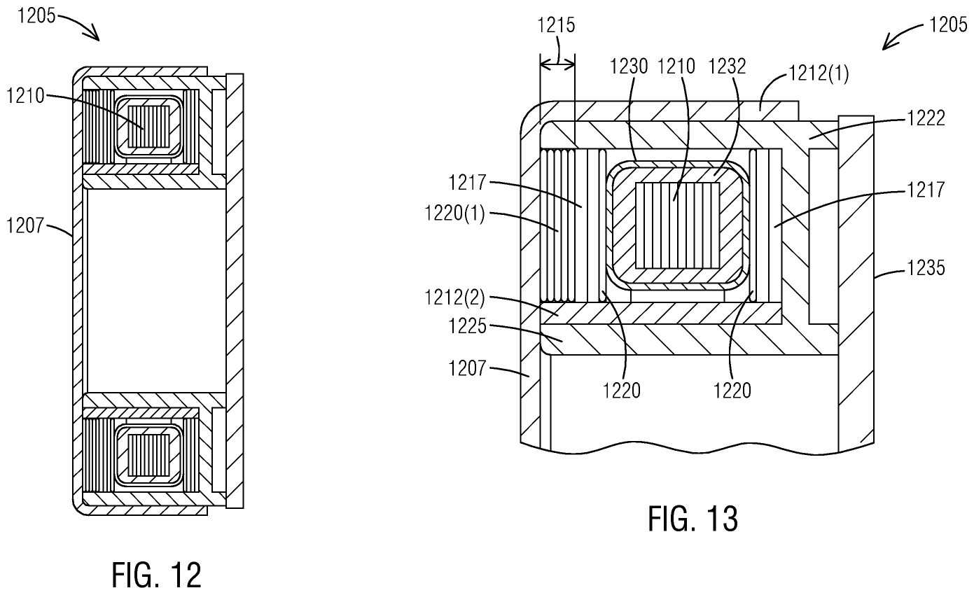

First is a differential CT with a 1-layer shield, optimized for a core with ring laminations. See FIGS. 12 and 13.

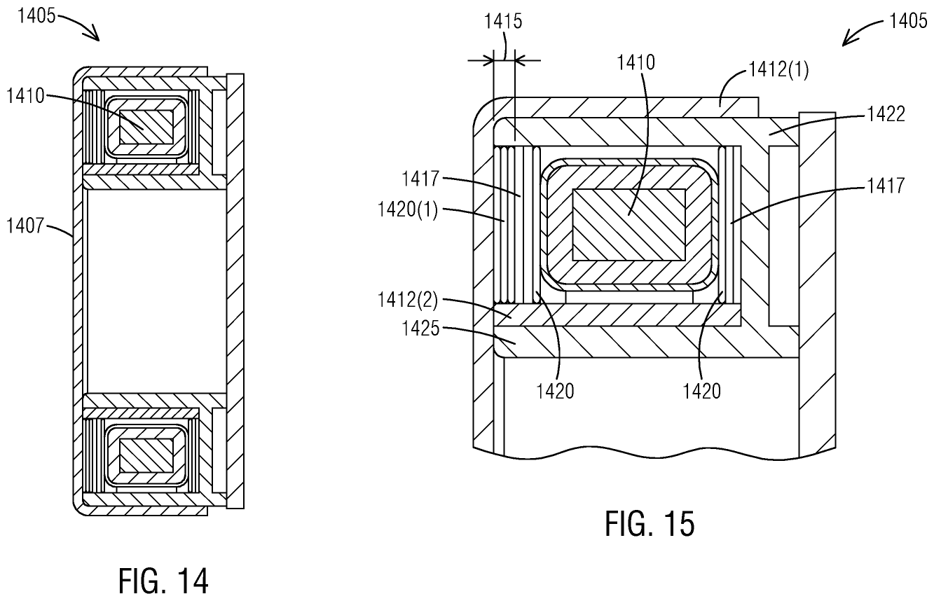

Second is a differential CT with a 1-layer shield, optimized for a tape-wound core. See FIGS. 14 and 15.

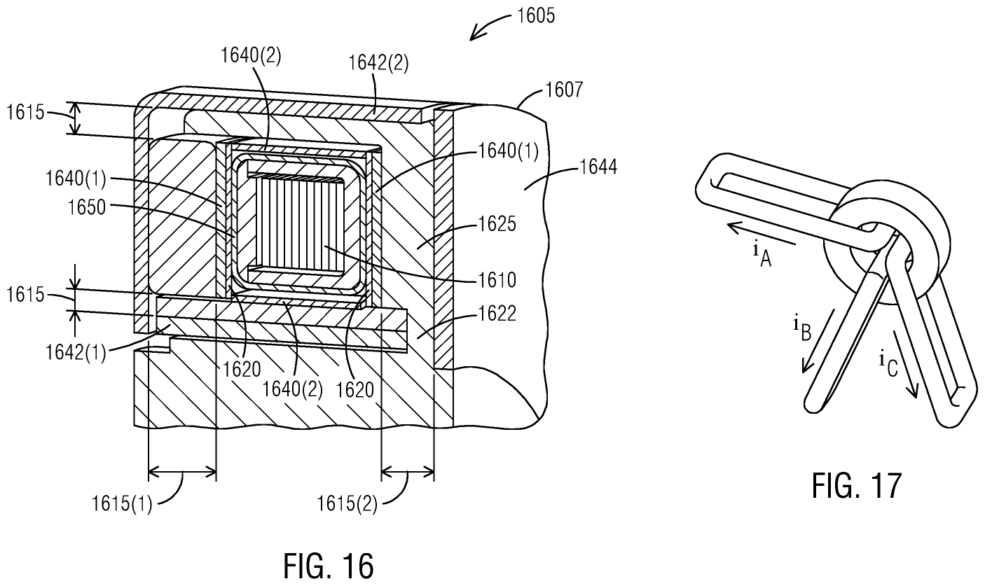

Third is a high-performance differential CT with a 2-layer shield. This configuration is suitable for either ring laminations or tape-wound cores. See FIG. 16.

FIG. 12 illustrates a section view of a first embodiment of the present invention (a ring lamination core). FIG. 13 illustrates an enlarged section view of the first embodiment of the present invention. The 1^{st} embodiment of the invention includes the following features:

The core is comprised of ring laminations.

Shielding is provided at all four locations: radially inside, radially outside, and both sides axially.

The shielding system is comprised of three different materials.

Silicon steel washers are stacked 3 pieces thick, because the ring lamination core requires strong shielding in the axial direction.

The outer shield is lower-cost low carbon steel because it blocks only external fields that are relatively weak compared to the fields produced by primary wires.

The mumetal inner shield blocks strong fields of the primary wires.

The electrical insulating feature provided by a CT housing is critical. If not present, there would be in effect short circuit loop around the core of the CT. There would be strong electrical currents in the shielding system that would affect the efficiency and accuracy of the CT and reduce shielding effectiveness.

The top of the outer shield comprises a second layer of shielding in addition to the silicon steel washers at the axial top location. For this 2^{nd} layer to be effective, it is critical that there be a magnetic air gap between the outer shield and the silicon washers. This is assured by adding insulating spacers. (Note that the term “magnetic air gap” does not necessarily mean the material is air. Rather, it means any material with relative permeability equal to 1, such as air, vacuum, most plastics, paper, etc.)

Insulating spacers are provided for secondary winding protection. These prevent contact between magnet wire and silicon steel washers, which might potentially short circuit the windings if there should be breakdown of the magnet wire insulation.

FIG. 12 illustrates a section view at a cutting plane A-A (FIG. 11) of a magnetic shielding system 1205 for a Differential Current Transformer 1207 with a ring lamination core 1210 to provide shielding at multiple locations (radially inside, radially outside, and both sides axially). FIG. 13 illustrates an enlarged section view of the magnetic shielding system 1205 for the Differential Current Transformer 1207 with the ring lamination core 1210.

The magnetic shielding system 1205 comprises an outer shield 1212(1) being cylindrically-shaped and closely fitting and an inner shield 1212(2) being closely fitting over four conductor cables that pass through the Differential Current Transformer 1207. An inside diameter of the inner shield 1212(2) is less than 1.5 times the diameter of the smallest circle that can enclose the four conductor cables that pass through the Differential Current Transformer 1207. In an axial direction, the magnetic shielding system 1205 comprises multiple layers of flat, washer-shaped parts in which at least one layer on top and one layer on bottom is of magnetic shielding material. Magnetic shielding is provided at the multiple locations using two or more different classes of materials.

The Differential Current Transformer 1207 is with a 1-layer shield, optimized for the core 1210 with ring laminations. The outer shield 1212(1) is a low carbon steel and the inner shield 1212(2) is a tubular ring of mumetal that blocks strong fields of primary wires. The magnetic shielding system 1205 further comprises a magnetic air gap 1215 with insulating spacers for the magnetic air gap 1215. The magnetic shielding system 1205 further comprises a plurality of magnetic shield washers 1217. The magnetic shielding system 1205 further comprises a plurality of insulating spacers 1220 for secondary winding protection. The magnetic shielding system 1205 further comprises a plurality of insulating spacers 1220(1) for air gap.

An electrical insulating feature 1222 is provided for the magnetic shielding system 1205 by a housing 1225 of the Differential Current Transformer 1207. The magnetic shielding system 1205 further comprises secondary winding 1230. The ring lamination core 1210 has a case 1232. The magnetic shielding system 1205 further comprises a printed circuit board portion 1235 for the Differential Current Transformer 1207. The shielding of the magnetic shielding system 1205 is comprised of three different materials. A top of the outer shield 1212(1) comprises a second layer of shielding in addition to low carbon steel washers at an axial top location.

FIG. 14 illustrates a section view of a second embodiment of the present invention (a tape wound core). FIG. 15 illustrates an enlarged section view of the second embodiment of the present invention. The 2^{nd} embodiment of the present invention is like the 1^{st} embodiment, but with the following differences. These differences would seem to be relatively minor, but they demonstrate the flexibility of the present invention as it can be adjusted according to different needs. It is characterized by the following features:

The core is tape-wound construction.

There are only 2 silicon steel washers on each side axially, because a tape-wound core is less sensitive to magnetic fields entering in the axial direction than is a ring lamination core.

The outer shield is made of mumetal rather than low-carbon steel, because a tape-wound core is more sensitive to magnetic fields entering from the radial direction than a ring lamination core.

FIG. 14 illustrates a section view at a cutting plane A-A′ (FIG. 11) of a magnetic shielding system 1405 for a Differential Current Transformer 1407 with a tape-wound core 1410 to provide shielding at multiple locations (radially inside, radially outside, and both sides axially). FIG. 15 illustrates an enlarged section view of the magnetic shielding system 1405 for the Differential Current Transformer 1407 with the tape-wound core 1410.

The magnetic shielding system 1405 comprises an outer shield 1412(1) being cylindrically shaped and closely fitting and an inner shield 1412(2) being closely fitting over four conductor cables that pass through the Differential Current Transformer 1407. An inside diameter of the inner shield 1412(2) is less than 1.5 times the diameter of the smallest circle that can enclose the four conductor cables that pass through the Differential Current Transformer 1407. In an axial direction, the magnetic shielding system 1405 comprises multiple layers of flat, washer-shaped parts in which at least one layer on top and one layer on bottom is of magnetic shielding material. Magnetic shielding is provided at the multiple locations using two or more different classes of materials.

The Differential Current Transformer 1407 is with a 1-layer shield, optimized for the tape-wound core 1410. In the magnetic shielding system 1405, there are one or more low carbon steel washers on each side axially. The outer shield 1412(1) is made of any magnetic shielding material from 80% Ni class of materials. The tape-wound core 1410 is a tape-wound construction of an 80% Ni alloy. The inner shield 1412(2) is a tubular ring of any magnetic shielding material from 80% Ni class of materials. The magnetic shielding system 1405 further comprises a magnetic air gap 1415 with insulating spacers for the magnetic air gap 1415. The magnetic shielding system 1405 further comprises a plurality of magnetic shield washers 1417. The magnetic shielding system 1405 further comprises a plurality of insulating spacers 1420 for secondary winding protection. The magnetic shielding system 1405 further comprises a plurality of insulating spacers 1420(1) for air gap. An electrical insulating feature 1422 is provided for the magnetic shielding system 1405 by a housing 1425 of the Differential Current Transformer 1407.

FIG. 16 illustrates an enlarged section view of a third embodiment of the present invention which provides higher magnetic shielding performance than the first and second embodiments. The 3rd embodiment of the invention is characterized by a 2-layer shielding system. This embodiment provides much greater attenuation of magnetic fields than the 1^{st} and 2^{nd} embodiments. It is characterized by the following features:

The core may be either ring laminations (as shown) or tape-wound.

There is a 1^{st} shielding layer nearest the core. Preferably, this is comprised of very high permeability material such as mumetal.

There is a 2^{nd} layer of shielding material surrounding the 1^{st} layer. Preferably, this is comprised of a high saturation material such as low carbon steel or high-purity iron.

There is a significant air gap between the 1^{st} and 2^{nd} layers at all 4 locations: radially inside, radially outside, and axially top and bottom. This air gap is critical and bigger is better. Therefore, it is maximized according to space available.

Both the 1^{st} and 2^{nd} layers are present at all 4 locations: radially inside, radially outside, and axially top and bottom.

There are electrical insulating features for both the 1^{st} and 2^{nd} layers to prevent short circuit loops which would cause strong electrical currents in the shielding system. For the 1^{st} layer, this is provided by insulating spacers; for the 2^{nd} layer, it is provided by the CT plastic housing.

In FIG. 16, a magnetic shielding system 1605 for a Differential Current Transformer 1607 provides shielding at multiple locations. The magnetic shielding system 1605 comprises a core 1610 that may be either ring laminations or tape-wound. The magnetic shielding system 1605 further comprises a first layer axial shields 1640(1) (top and bottom made of any magnetic shielding material from 80% Ni class of materials) and a first layer radial shields 1640(2) (inner and outer made of any magnetic shielding material from 80% Ni class of materials). The magnetic shielding system 1605 further comprises a second layer radial inner shield 1642(1), a second layer radial outer shield 1642(2) and a second layer axial shield bottom 1644.

The magnetic shielding system 1605 further comprises a housing 1625 of the Differential Current Transformer 1607 such that shielding is characterized by a 2-layer shielding system. Both first and second layers of shielding are present at locations: radially inside, radially outside, and axially top and bottom. A material of the second layer of shielding surrounds the first layer of the shielding, and the first layer of shielding is nearest to the core 1610.

The magnetic shielding system 1605 further comprises a secondary winding magnet wire 1650 in one or more layers. The first layer of shielding is comprised of a very high permeability material including mumetal, and the second layer of shielding material is comprised of a high saturation material including a low carbon steel or a high-purity iron.

The magnetic shielding system 1605 further comprises a plurality of insulating spacers 1620. An electrical insulating feature 1622 is provided for the magnetic shielding system 1605 by a housing 1625 of the Differential Current Transformer 1607. The second layer radial outer shield and the second layer axial shield bottom 1644 are a low carbon steel and the tape-wound core 1610 is a tape-wound construction of an 80% Ni alloy. The magnetic shielding system 1605 further comprises a plurality of magnetic air gaps 1615 (magnetic air gap, outer and inner radial, 1615(1) (magnetic air gap, axial top), 1615(2) (magnetic air gap, axial bottom).

Because present invention provides more shielding protection than other solutions inside a circuit breaker while maintaining compactness, this allows the circuit breaker to have much higher continuous current ratings than prior art. Current GFCI circuit breaker is rated 100A, versus 60A for prior art.

The differential CT of instant invention is compact and is incorporated inside a circuit breaker housing. By performing magnetic simulations, the shielding parts are dimensioned so that the differential CT works not only for basic GFCI functioning, but also avoids nuisance tripping at overload levels required for a circuit breaker. A 1-layer embodiment of the shielding system has been demonstrated to work at a 100A continuous current rating, meets the 4-6 mA tripping threshold range and does not nuisance trip on 600A overloads.

A prior art 3-phase GFCI circuit breaker may provide shielding. However, their shielding is box-shaped and not compact. The inside diameter of their CT is greatly oversized compared to the primary wires. As a result, their CT is too large to fit inside a reasonably or competitively sized circuit breaker. By contrast, present invention is using a cylindrically shaped outer shield, which allows it to conform more closely to a toroidal core, and the inside diameter of instant CT is made as small as possible, limited by the diameter of the primary wires.

Instant shielding system is using multiple shielding materials. Materials may be selected to be optimal for each of the 4 different locations. This gives better ability to protect against both strong and weak magnetic fields. It allows optimization of cost because more expensive materials are used only where needed.

Instant shielding system provides flexibility for future adjustments. Different combinations of materials may be substituted without major tooling changes. The shielding system may therefore be adapted to different ratings requirements or further optimized for cost without requiring a large financial investment.

The 3^{rd} embodiment of the present invention provides high performance beyond the present need. Magnetic field attenuation is 3 orders of magnitude better than the 1^{st} or 2^{nd} embodiments. This solution may potentially be used for even higher current ratings than 100A. Alternatively it might be used in more severe environments that have very strong external magnetic fields. It achieves this high performance with only a moderate cost and size increase.

The following FIGs. demonstrate the attenuation of a magnetic field on a magnetic core (ring laminations core, tape-wound core) of a differential CT that present invention provides.

FIG. 17 shows a magnetic simulation setup. This is a 3-phase balanced current at 600A RMS. Ideally, the net flux in the magnetic core should be zero at all moments in time. Phase angles are offset from each other by 120 degrees so net primary current through the differential CT is always zero. Therefore, net flux around the core is ideally zero.

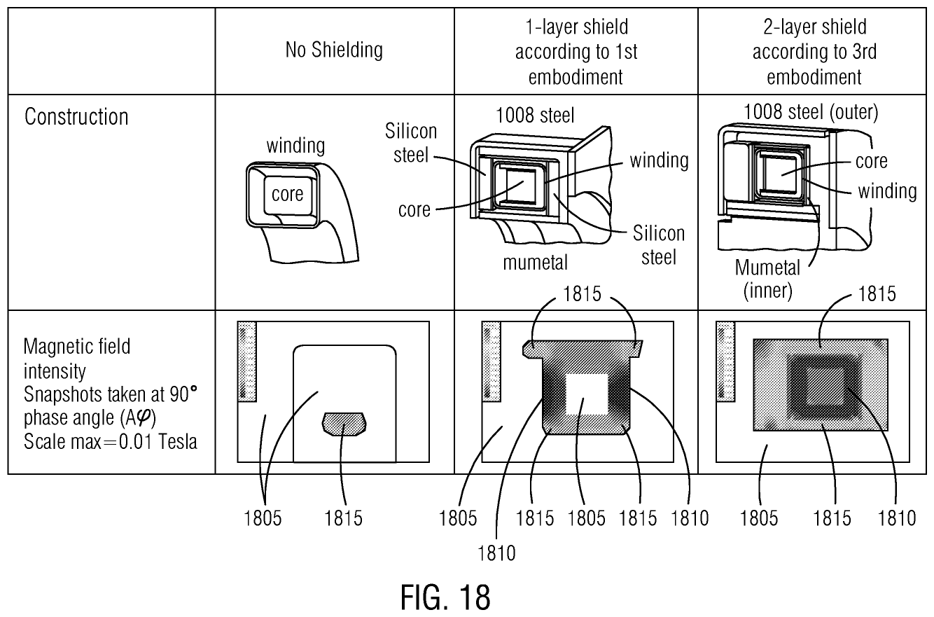

FIG. 18 shows a worst-case magnetic field intensity on a cross-section of the setup of FIG. 17. First area 1805 shows areas that exceed the color scale maximum of 0.01 Tesla for the plot. Second and third areas 1810, 1815 show the attenuated magnetic field inside the magnetic shielding. First area 1805 indicates magnetic field exceeds the scale maximum of 0.01 Tesla.

The 1-layer shield shows strong flux attenuation. However, enough flux penetrates so that the field in the magnetic core is above 0.01 Tesla. Nevertheless, this is sufficient attenuation that the differential CT meets the requirements of UL 943.

The 2-layer shield shows strong and successive attenuation by each layer of the shield. The 2^{nd} layer blocks the strongest fields and lets only weaker fields penetrate to reach the 1^{st} layer. Inside the first layer, magnetic field intensity is extremely low. The core has a field intensity much less than 0.01 Tesla, despite its extremely high permeability.

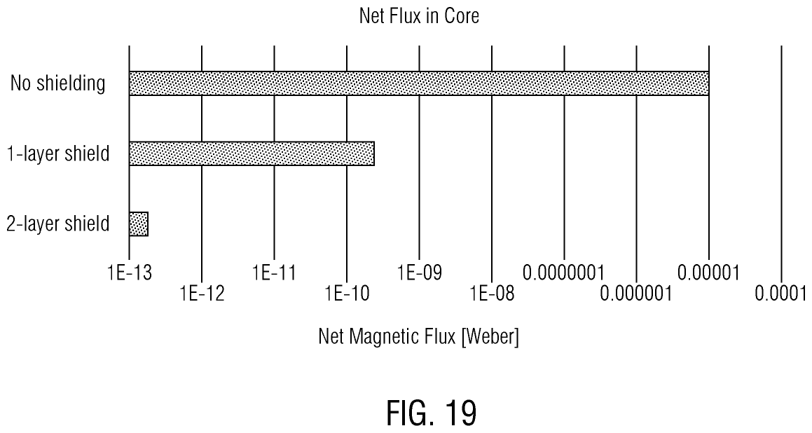

FIG. 19 shows a maximum net flux around the magnetic core for the setup shown in FIG. 17. The 1-layer shield attenuates flux by 4 orders of magnitude. The 2-layer shield attenuates flux by 7 orders of magnitude.

A differential current transformer (CT) example is shown; however, instant magnetic shielding system could be used on other types of current transformers. A toroidal or an oval transformer example is shown; however, it is less likely that instant magnetic shielding system could be used on rectangular transformers. A current transformer is used inside a circuit breaker, especially a differential current transformer (CT) inside a GFCI circuit breaker. The core of the differential current transformer (CT) is of a high permeability material with max relative permeability 20,000 or greater.

The differential current transformer (CT) has multi-location magnetic shielding. The magnetic shielding is present at all four locations: radially inside, radially outside, and both sides axially. The magnetic shielding material is multi-piece, so that it can be optionally comprised of 2 or more different types of materials. The magnetic shielding system is capable to be configured in at least two different configurations, a first configuration that is more optimal for a ring-laminated core, and a second configuration that is more optimal for a tape-wound core.

Optionally, the differential current transformer (CT) is using silicon steel flat washer-shaped parts axially top and bottom as shielding. Optionally, the differential current transformer (CT) uses multiple pieces of silicon steel flat washer-shaped parts stacked together. Optionally, the differential current transformer (CT) has a deep-drawn outer shield, with insulating spacers that create a magnetic air gap between the outer shield and the top axial shielding material (such as silicon steel washers).

As a further optional alternative, the differential current transformer (CT) has a 2-layer shielding system:
a. Each layer has magnetic shielding present at all four locations: radially inside, radially outside, and both sides axially.
b. There is an air gap between the 2 layers of shielding at all four locations, preferably. However, if an air gap is omitted from one or two locations, a partial advantage will still be gained that agrees with present invention.
c. Optionally, the 1^{st} inside layer is comprised of high permeability shielding materials, and the 2^{nd} outer layer is comprised of high magnetic saturation materials.

While a differential current transformer (CT) is described here a range of one or more other current transformers are also contemplated by the present invention. For example, other current transformers may be implemented based on one or more features presented above without deviating from the spirit of the present invention.

The techniques described herein can be particularly useful for a magnetic core with ring laminations or tape-wound construction. While particular embodiments are described in terms of a magnetic core with ring laminations or tape-wound construction, the techniques described herein are not limited to such a core but can also be used with other types of cores.

While embodiments of the present invention have been disclosed in exemplary forms, it will be apparent to those skilled in the art that many modifications, additions, and deletions can be made therein without departing from the spirit and scope of the invention and its equivalents, as set forth in the following claims.

Embodiments and the various features and advantageous details thereof are explained more fully with reference to the non-limiting embodiments that are illustrated in the accompanying drawings and detailed in the following description. Descriptions of well-known starting materials, processing techniques, components and equipment are omitted so as not to unnecessarily obscure embodiments in detail. It should be understood, however, that the detailed description and the specific examples, while indicating preferred embodiments, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising,” “includes,” “including,” “has,” “having” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus.

Additionally, any examples or illustrations given herein are not to be regarded in any way as restrictions on, limits to, or express definitions of, any term or terms with which they are utilized. Instead, these examples or illustrations are to be regarded as being described with respect to one particular embodiment and as illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms.

In the foregoing specification, the invention has been described with reference to specific embodiments. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of invention.

Although the invention has been described with respect to specific embodiments thereof, these embodiments are merely illustrative, and not restrictive of the invention. The description herein of illustrated embodiments of the invention is not intended to be exhaustive or to limit the invention to the precise forms disclosed herein (and in particular, the inclusion of any particular embodiment, feature or function is not intended to limit the scope of the invention to such embodiment, feature or function). Rather, the description is intended to describe illustrative embodiments, features and functions in order to provide a person of ordinary skill in the art context to understand the invention without limiting the invention to any particularly described embodiment, feature or function. While specific embodiments of, and examples for, the invention are described herein for illustrative purposes only, various equivalent modifications are possible within the spirit and scope of the invention, as those skilled in the relevant art will recognize and appreciate. As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the invention.

Respective appearances of the phrases “in one embodiment,” “in an embodiment,” or “in a specific embodiment” or similar terminology in various places throughout this specification are not necessarily referring to the same embodiment. Furthermore, the particular features, structures, or characteristics of any particular embodiment may be combined in any suitable manner with one or more other embodiments. It is to be understood that other variations and modifications of the embodiments described and illustrated herein are possible in light of the teachings herein and are to be considered as part of the spirit and scope of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

It will also be appreciated that one or more of the elements depicted in the drawings/figures can also be implemented in a more separated or integrated manner, or even removed or rendered as inoperable in certain cases, as is useful in accordance with a particular application.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component.

What is claimed is:

1. A magnetic shielding system for a Differential Current Transformer to provide shielding at multiple locations, the magnetic shielding system comprising:
an outer shield being cylindrically-shaped and closely fitting; and
an inner shield being closely fitting over four conductor cables that pass through the Differential Current Transformer;
wherein an inside diameter of the inner shield is less than 1.5 times the diameter of the smallest circle that can enclose the four conductor cables that pass through the Differential Current Transformer,
wherein in an axial direction, the magnetic shielding system comprises multiple layers of flat, washer-shaped parts in which at least one layer on top and one layer on bottom is of magnetic shielding material, and
wherein magnetic shielding is provided at the multiple locations using two or more different classes of materials.

2. The magnetic shielding system of claim 1, wherein the Differential Current Transformer is with a 1-layer shield, optimized for a magnetic core with ring laminations.

3. The magnetic shielding system of claim 2, wherein the outer shield is a low carbon steel and the inner shield is a tubular ring of mumetal that blocks strong fields of primary wires.

4. The magnetic shielding system of claim 3, further comprising:
a magnetic air gap with insulating spacers for the magnetic air gap;
a plurality of magnetic shield washers; and
a plurality of insulating spacers for secondary winding protection.

5. The magnetic shielding system of claim 4, wherein an electrical insulating feature is provided for the magnetic shielding system by a housing of the Differential Current Transformer.

6. The magnetic shielding system of claim 5, wherein the magnetic shielding system is comprised of three different materials.

7. The magnetic shielding system of claim 6, wherein a top of the outer shield comprises a second layer of shielding in addition to low carbon steel washers at an axial top location.

8. The magnetic shielding system of claim 1, wherein the Differential Current Transformer is with a 1-layer shield, optimized for a tape-wound core.

9. The magnetic shielding system of claim 8, wherein there are one or more low carbon steel washers on each side axially.

10. The magnetic shielding system of claim 9, wherein the outer shield is made of any magnetic shielding material from 80% Ni class of materials.

11. The magnetic shielding system of claim 10, wherein the tape-wound core is a tape-wound construction of an 80% Ni alloy.

12. The magnetic shielding system of claim 11, wherein the inner shield is a tubular ring of any magnetic shielding material from 80% Ni class of materials.

13. The magnetic shielding system of claim 12, further comprising:
a magnetic air gap with insulating spacers for the magnetic air gap;
a plurality of magnetic shield washers; and
a plurality of insulating spacers for secondary winding protection.

14. The magnetic shielding system of claim 13, wherein an electrical insulating feature is provided for the magnetic shielding system by a housing of the Differential Current Transformer.

15. A magnetic shielding system for a Differential Current Transformer to provide shielding at multiple locations, the magnetic shielding system comprises:
a magnetic core that may be either ring laminations or tape-wound;
a first layer axial shields (top and bottom made of any magnetic shielding material from 80% Ni class of materials);
a first layer radial shields (inner and outer made of any magnetic shielding material from 80% Ni class of materials);
a second layer radial inner shield;
a second layer radial outer shield;
a second layer axial shield bottom; and
a housing of the Differential Current Transformer, wherein shielding is characterized by a 2-layer shielding system,
wherein both first and second layers of shielding are present at locations: radially inside, radially outside, and axially top and bottom, and
wherein a material of the second layer of shielding surrounds the first layer of the shielding, and wherein the first layer of shielding is nearest to the core.

16. The magnetic shielding system of claim 15, further comprising:
a secondary winding magnet wire in one or more layers, wherein the first layer of shielding is comprised of a very high permeability material including mumetal, and wherein the second layer of shielding material is comprised of a high saturation material including a low carbon steel or a high-purity iron.

17. The magnetic shielding system of claim 16, further comprising:
a plurality of insulating spacers.

18. The magnetic shielding system of claim 17, wherein an electrical insulating feature is provided for the magnetic shielding system by a housing of the Differential Current Transformer.

19. The magnetic shielding system of claim 18, wherein the second layer radial outer shield and the second layer axial shield bottom are a low carbon steel and wherein the tape-wound core is a tape-wound construction of an 80% Ni alloy.

20. The magnetic shielding system of claim 19, further comprising:
a plurality of magnetic air gaps.
